(19) United States
(12) Patent Application Publication
(10) Pub. No.: US 2006/0075967 A1
(43) Pub. Date: Apr. 13, 2006

(54) Magnetic-field concentration in inductively coupled plasma reactors

(75) Inventors: Siqing Lu, San Jose, CA (US); Canfeng Lai, Fremont, CA (US); Qiwei Liang, Fremont, CA (US); Maolin Long, Santa Clara, CA (US); Irene Chou, San Jose, CA (US); Jason Bloking, Santa Clara, CA (US); Steven H. Kim, Union City, CA (US); Ellie Y. Yieh, San Jose, CA (US)

Correspondence Address: Patent Counsel;Applied Materials, Inc., Legal Affairs Department, M/S 2061, P.O. Box 450A, Santa Clara, CA, 95052, US

(73) Assignee: APPLIED MATERIALS, INC., Santa Clara, CA (US)

(21) Appl. No.: 10/963,030

(22) Filed: Oct. 12, 2004

(51) Int. Cl. H01L 21/20; C23C 16/00

(52) U.S. Cl. 118/723 I; 438/478

(57) ABSTRACT

A substrate processing system is provided with a housing defining a process chamber. A substrate holder is disposed within the process chamber and configured to support a substrate during substrate processing. A gas delivery system is configured to introduce a gas into the process chamber. A pressure-control system is provided for maintaining a selected pressure within the process chamber. A high-density-plasma generating system is operatively coupled with the process chamber and includes a coil for inductively coupling energy into a plasma formed within the process chamber. It also includes magneto-dielectric material proximate the coil for concentrating a magnetic field generated by the coil. A controller is also provided for controlling the gas-delivery system, the pressure-control system, and the high-density-plasma generating system.

### BACKGROUND OF THE INVENTION

One of the primary steps in the fabrication of modern semiconductor devices is the formation of a film, such as a silicon oxide film, on a semiconductor substrate. Silicon oxide is widely used as an insulating layer in the manufacture of semiconductor devices. As is well known, a silicon oxide film can be deposited by a thermal chemical-vapor deposition (“CVD”) process or by a plasma-enhanced chemical-vapor deposition (“PECVD”) process. In a conventional thermal CVD process, reactive gases are supplied to a surface of the substrate, where heat-induced chemical reactions take place to produce a desired film. In a conventional plasma-deposition process, a controlled plasma is formed to decompose and/or energize reactive species to produce the desired film.

Semiconductor device geometries have decreased significantly in size since such devices were first introduced several decades ago, and continue to be reduced in size. This continuing reduction in the scale of device geometry has resulted in a dramatic increase in the density of circuit elements and interconnections formed in integrated circuits fabricated on a semiconductor substrate. One persistent challenge faced by semiconductor manufacturers in the design and fabrication of such densely packed integrated circuits is the desire to prevent spurious interactions between circuit elements, a goal that has required ongoing innovation as geometry scales continue to decrease.

Unwanted interactions are typically prevented by providing spaces between adjacent elements that are filled with an electrically insulative material to isolate the elements both physically and electrically. Such spaces are sometimes referred to herein as “gaps” or “trenches,” and the processes for filling such spaces are commonly referred to in the art as “gapfill” processes. The ability of a given process to produce a film that completely fills such gaps is thus often referred to as the “gapfill ability” of the process, with the film described as a “gapfill layer” or “gapfill film.” As circuit densities increase with smaller feature sizes, the widths of these gaps decrease, resulting in an increase in their aspect ratio, which is defined by the ratio of the gap's height to its depth. High-aspect-ratio gaps are difficult to fill completely using conventional CVD techniques, which tend to have relatively poor gapfill abilities. One family of electrically insulating films that is commonly used to fill gaps in intermetal dielectric (“IMD”) applications, premetal dielectric (“PMD”) applications, and shallow-trench-isolation (“STI”) applications, among others, is silicon oxide (sometimes also referred to as “silica glass” or “silicate glass”).

Some integrated circuit manufacturers have turned to the use of high-density plasma CVD (“HDP-CVD”) systems in depositing silicon oxide gapfill layers. Such systems form a plasma that has a density greater than about 10¹¹ ions/cm³, which is about two orders of magnitude greater than the plasma density provided by a standard capacitively coupled plasma CVD system. Inductively coupled plasma (“ICP”) systems are examples of HDP-CVD systems. One factor that allows films deposited by such HDP-CVD techniques to have improved gapfill characteristics is the occurrence of sputtering simultaneous with deposition of material. Sputtering is a mechanical process by which material is ejected by impact, and is promoted by the high ionic density of the plasma in HDP-CVD processes. The sputtering component of HDP deposition thus slows deposition on certain features, such as the corners of raised surfaces, thereby contributing to the increased gap fill ability.

It is generally desirable to increase the plasma density to improve the characteristics of a number of deposition processes, including gapfill processes in particular, but there are practical limits to densities that may be achieved with current plasma-reactor designs. For example, ICP reactors generally couple energy into the plasma using the inductive properties of radio-frequency (“RF”) coils. One way of increasing the plasma density with such a reactor is to increase the power provided to the RF coils. Such an approach has a number of adverse effects that are a consequence of resulting increasing in heat losses. As temperatures rise because of the increased power, there is a greater risk of parts in the reactor burning out. In addition, the excess heat affects ceramic parts that are commonly included in such reactors, resulting in the generation of more particulates that flake from the ceramic parts and that consequently contaminate the film being deposited.

There is accordingly a general need in the art for improved systems for concentrating power in the plasma of ICP reactors without such adverse effects.

### BRIEF SUMMARY OF THE INVENTION

Embodiments of the invention provide methods and systems that include a magneto-dielectric material as part of an RF coil assembly in an ICP reactor to concentrate magnetic fields generated by the RF coil. This may permit both the plasma density to be increased and for the plasma uniformity to be improved.

In one set of embodiments, a substrate processing system is provided with a housing defining a process chamber. A substrate holder is disposed within the process chamber and configured to support a substrate during substrate processing. A gas delivery system is configured to introduce a gas into the process chamber. A pressure-control system is provided for maintaining a selected pressure within the process chamber. A high-density-plasma generating system is operatively coupled with the process chamber and includes a coil for inductively coupling energy into a plasma formed within the process chamber. It also includes magneto-dielectric material proximate the coil for concentrating a magnetic field generated by the coil. A controller is also provided for controlling the gas-delivery system, the pressure-control system, and the high-density-plasma generating system.

In some embodiments, the magneto-dielectric material comprises a ferromagnetic material and a dielectric material, with the dielectric material provided at greater than 2 wt. % of the magneto-dielectric material; in other embodiments the dielectric material is provided at greater than 10 wt. % of the magneto-dielectric material. The ferromagnetic material may comprise iron and the dielectric material may comprise an epoxy resin. The magneto-dielectric material may have a thermal conductivity greater than 2 W/mK and in one embodiment has a thermal conductivity between 2 and 10 W/mK. It may have an electrical resistivity greater than 10³ Ω cm and in one embodiment has an electrical resistivity between 10³ and 10⁸ Ω cm. It may also have a residual permittivity greater than 15 and in one embodiment has a residual permittivity between 15 and 25. In addition, it may have a relative permeability greater than 14 and in one embodiment has a relative permeability between 14 and 50.

In another set of embodiments, a method is provided for depositing a film on a substrate disposed in a substrate processing chamber. A process gas is flowed into the substrate processing chamber. A plasma is formed inductively from the process gas with a coil to have an ion density greater than 10¹¹ ions/cm³. A magnetic field generated by the coil is concentrated with a magneto-dielectric material disposed proximate the coil. The film is deposited over the substrate with the plasma in a process that has simultaneous deposition and sputtering components.

In some instances, the substrate may have a trench formed between adjacent raised surfaces, with the film being deposited over the substrate and within the trench. To deposit a silicon oxide film, the process gas may comprise a silicon source, an oxygen source, and a fluent gas. The fluent gas may comprise He and/or H₂ in different embodiments. The magneto-dielectric material may have the composition and properties described above in various embodiments.

A further understanding of the nature and advantages of the present invention may be realized by reference to the remaining portions of the specification and the drawings.

### BRIEF DESCRIPTION OF THE DRAWINGS

FIG. 1 is a simplified cross-sectional view of an exemplary ICP reactor system according to an embodiment of the invention;

FIG. 2 shows a coil assembly that includes a magneto-dielectric material to act as a magnetic-field concentrator;

FIGS. 3A and 3B are micrographs of a magneto-dielectric material used in some embodiments of the invention;

FIGS. 4A and 4B are graphs that show magnetic properties of the magneto-dielectric material shown in FIGS. 3A and 3B;

FIGS. 5A and 5B show the results of simulations of magnetic fields that are formed with coil assemblies that respectively lack and include a magneto-dielectric material to act as a magnetic-field concentrator;

FIG. 6 is a flow diagram illustrating a method for filling gaps using an HDP process in an ICP reactor of the invention;

FIGS. 7A-7B are micrographs showing gapfill characteristics for HDP processes at wafer centers and edges to compare processes performed in ICP reactors with and without magnetic-field concentrators provided in accordance with embodiments of the invention.

### DETAILED DESCRIPTION OF THE INVENTION

Embodiments of the invention provide an ICP reactor that includes magnetic-field concentrators as part of coil assemblies used for inductive coupling of power into plasmas formed within a chamber of the ICP reactor. In certain embodiments, the magnetic-field concentrators comprise a magneto-dielectric material, which acts to lower the effective electric conductivity and increase the effective magnetic conductivity while maintaining relatively high thermal conductivity of the coil assemblies. The effect of such a combination is to concentrate the magnetic field generated by the inductive coils substantially without the production of eddy currents, which in turn permits the formation of denser plasmas without significant temperature changes.

These effects are due in part to the dielectric characteristics of the magneto-dielectric material. For example, while the magnetic field could be concentrated by use of a metallic material, such a material would not act to effectively suppress the formation of eddy currents within the metal so that the process would be accompanied by the undesirable effects associated with excess heat production. As illustrated by measurements discussed more fully in the detailed description set forth below, the inventors have found no appreciable temperature change during plasma processes even while achieving improved performance characteristics as a result of the magnetic-field concentration.

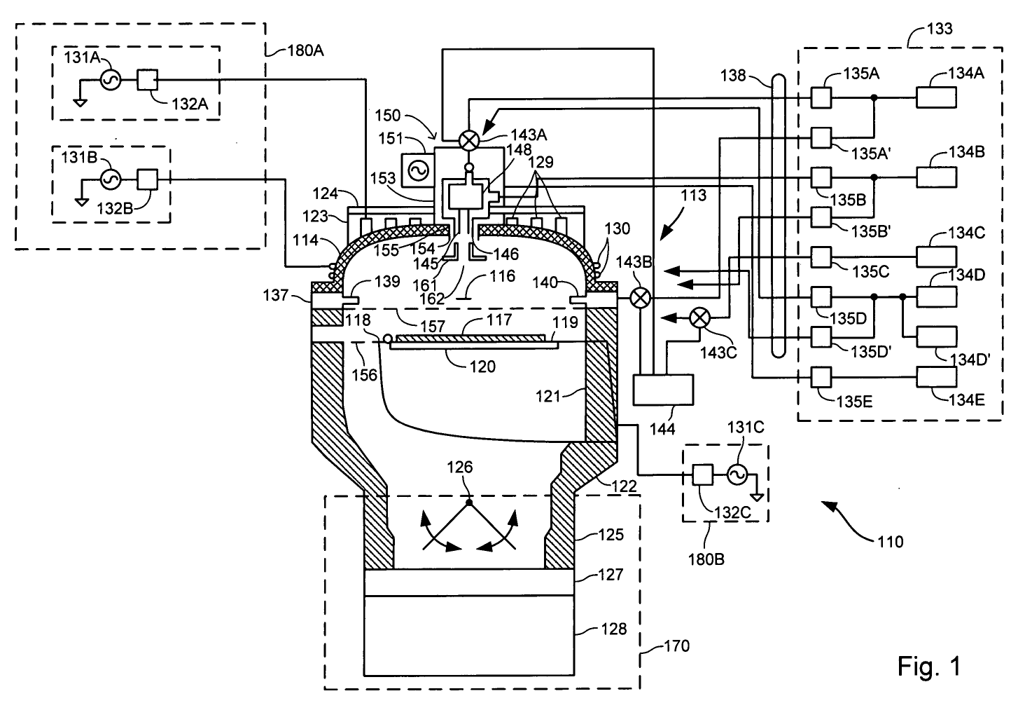

The inventors have implemented embodiments of the invention with the ULTIMA™ system manufactured by APPLIED MATERIALS, INC., of Santa Clara, Calif., a general description of which is provided in commonly assigned U.S. Pat. No. 6,170,428, “SYMMETRIC TUNABLE INDUCTIVELY COUPLED HDP-CVD REACTOR,” filed Jul. 15, 1996 by Fred C. Redeker, Farhad Moghadam, Hirogi Hanawa, Tetsuya Ishikawa, Dan Maydan, Shijian Li, Brian Lue, Robert Steger, Yaxin Wang, Manus Wong and Ashok Sinha, the entire disclosure of which is incorporated herein by reference. An overview of the ICP reactor is provided in connection with FIG. 1 below. The ICP reactor is part of an HDP-CVD system 110 that includes a chamber 113, a vacuum system 170, a source plasma system 180A, a bias plasma system 180B, a gas delivery system 133, and a remote plasma cleaning system 150. The upper portion of chamber 113 includes a dome 114, which is made of a ceramic dielectric material, such as aluminum oxide or aluminum nitride. Dome 114 defines an upper boundary of a plasma processing region 116. Plasma processing region 116 is bounded on the bottom by the upper surface of a substrate 117 and a substrate support member 118.

A heater plate 123 and a cold plate 124 surmount, and are thermally coupled to, dome 114. Heater plate 123 and cold plate 124 allow control of the dome temperature to within about ±10° C. over a range of about 100° C. to 200° C. This allows optimizing the dome temperature for the various processes. For example, it may be desirable to maintain the dome at a higher temperature for cleaning or etching processes than for deposition processes. Accurate control of the dome temperature also reduces the flake or particle counts in the chamber and improves adhesion between the deposited layer and the substrate.

The lower portion of chamber 113 includes a body member 122, which joins the chamber to the vacuum system. A base portion 121 of substrate support member 118 is mounted on, and forms a continuous inner surface with, body member 122. Substrates are transferred into and out of chamber 113 by a robot blade (not shown) through an insertion/removal opening (not shown) in the side of chamber 113. Lift pins (not shown) are raised and then lowered under the control of a motor (also not shown) to move the substrate from the robot blade at an upper loading position 157 to a lower processing position 156 in which the substrate is placed on a substrate receiving portion 119 of substrate support member 118. Substrate receiving portion 119 includes an electrostatic chuck 120 that secures the substrate to substrate support member 118 during substrate processing. In a preferred embodiment, substrate support member 118 is made from an aluminum oxide or aluminum ceramic material.

Vacuum system 170 includes throttle body 125, which houses twin-blade throttle valve 126 and is attached to gate valve 127 and small-molecule-enhanced turbomolecular pump 128. As described in detail below, the turbomolecular pump 128 has the modified performance characteristics making it suitable for efficient exhaustion of low-mass molecular species. It should be noted that throttle body 125 offers minimum obstruction to gas flow, and allows symmetric pumping. Gate valve 127 can isolate pump 128 from throttle body 125, and can also control chamber pressure by restricting the exhaust flow capacity when throttle valve 126 is fully open. The arrangement of the throttle valve, gate valve, and small-molecule-enhanced turbomolecular pump allow accurate and stable control of chamber pressures from between about 2 millitorr to about 2 torr.

The source plasma system 180A includes a top coil 129 and side coil 130, mounted on dome 114. A symmetrical ground shield (not shown) reduces electrical coupling between the coils. Top coil 129 is powered by top source RF (SRF) generator 131A, whereas side coil 130 is powered by side SRF generator 131B, allowing independent power levels and frequencies of operation for each coil. This dual coil system allows control of the radial ion density in chamber 113, thereby improving plasma uniformity. Side coil 130 and top coil 129 are typically inductively driven, which does not require a complimentary electrode. In a specific embodiment, the top source RF generator 131A provides up to 2,500 watts of RF power at nominally 2 MHz and the side source RF generator 131B provides up to 5,000 watts of RF power at nominally 2 MHz. The operating frequencies of the top and side RF generators may be offset from the nominal operating frequency (e.g. to 1.7-1.9 MHz and 1.9-2.1 MHz, respectively) to improve plasma-generation efficiency.

A bias plasma system 180B includes a bias RF (“BRF”) generator 131C and a bias matching network 132C. The bias plasma system 180B capacitively couples substrate portion 117 to body member 122, which act as complimentary electrodes. The bias plasma system 180B serves to enhance the transport of plasma species (e.g., ions) created by the source plasma system 180A to the surface of the substrate. In a specific embodiment, bias RF generator provides up to 5,000 watts of RF power at 13.56 MHz.

RF generators 131A and 131B include digitally controlled synthesizers and operate over a frequency range between about 1.8 to about 2.1 MHz. Each generator includes an RF control circuit (not shown) that measures reflected power from the chamber and coil back to the generator and adjusts the frequency of operation to obtain the lowest reflected power, as understood by a person of ordinary skill in the art. RF generators are typically designed to operate into a load with a characteristic impedance of 50 ohms. RF power may be reflected from loads that have a different characteristic impedance than the generator. This can reduce power transferred to the load. Additionally, power reflected from the load back to the generator may overload and damage the generator. Because the impedance of a plasma may range from less than 5 ohms to over 900 ohms, depending on the plasma ion density, among other factors, and because reflected power may be a function of frequency, adjusting the generator frequency according to the reflected power increases the power transferred from the RF generator to the plasma and protects the generator. Another way to reduce reflected power and improve efficiency is with a matching network.

Matching networks 132A and 132B match the output impedance of generators 131A and 131B with their respective coils 129 and 130. The RF control circuit may tune both matching networks by changing the value of capacitors within the matching networks to match the generator to the load as the load changes. The RF control circuit may tune a matching network when the power reflected from the load back to the generator exceeds a certain limit. One way to provide a constant match, and effectively disable the RF control circuit from tuning the matching network, is to set the reflected power limit above any expected value of reflected power. This may help stabilize a plasma under some conditions by holding the matching network constant at its most recent condition.

Other measures may also help stabilize a plasma. For example, the RF control circuit can be used to determine the power delivered to the load (plasma) and may increase or decrease the generator output power to keep the delivered power substantially constant during deposition of a layer.

A gas delivery system 133 provides gases from several sources, 134A-134E chamber for processing the substrate via gas delivery lines 138 (only some of which are shown). As would be understood by a person of skill in the art, the actual sources used for sources 134A-134E and the actual connection of delivery lines 138 to chamber 113 varies depending on the deposition and cleaning processes executed within chamber 113. Gases are introduced into chamber 113 through a gas ring 137 and/or a top nozzle 145. A plurality of source gas nozzles 139 (only one of which is shown in the illustration) provide a uniform flow of gas over the substrate. Nozzle length and nozzle angle may be changed to allow tailoring of the uniformity profile and gas utilization efficiency for a particular process within an individual chamber. In one embodiment, twelve source gas nozzles made from an aluminum oxide ceramic are provided.

In addition, a plurality of oxidizer gas nozzles 140 (only one of which is shown), which in a preferred embodiment are co-planar with and shorter than source gas nozzles 139. In some embodiments it is desirable not to mix source gases and oxidizer gases before injecting the gases into chamber 113. In other embodiments, oxidizer gas and source gas may be mixed prior to injecting the gases into chamber 113. In one embodiment, third, fourth, and fifth gas sources, 134C, 134D, and 134D′, and third and fourth gas flow controllers, 135C and 135D′, provide gas to body plenum via gas delivery lines 138. Additional valves, such as 143B (other valves not shown), may shut off gas from the flow controllers to the chamber.

In embodiments where flammable, toxic, or corrosive gases are used, it may be desirable to eliminate gas remaining in the gas delivery lines after a deposition. This may be accomplished using a 3-way valve, such as valve 143B, to isolate chamber 113 from the delivery lines and to vent the delivery lines to vacuum foreline 144, for example. As shown in FIG. 1, other similar valves, such as 143A and 143C, may be incorporated on other gas delivery lines. Such three-way valves may be placed as close to chamber 113 as practical, to minimize the volume of the unvented gas delivery line (between the three-way valve and the chamber). Additionally, two-way (on-off) valves (not shown) may be placed between a mass flow controller (“MFC”) and the chamber or between a gas source and an MFC.

The chamber 113 also has top nozzle 145 and top vent 146. Top nozzle 145 and top vent 146 allow independent control of top and side flows of the gases, which improves film uniformity and allows fine adjustment of the film's deposition and doping parameters. Top vent 146 is an annular opening around top nozzle 145. In one embodiment, first gas source 134A supplies source gas nozzles 139 and top nozzle 145. Source nozzle MFC 135A′ controls the amount of gas delivered to source gas nozzles 139 and top nozzle MFC 135A controls the amount of gas delivered to top gas nozzle 145. Similarly, two MFCs 135B and 135B′ may be used to control the flow of oxygen to both top vent 146 and oxidizer gas nozzles 140 from a single source of oxygen, such as source 134B. In some embodiments, oxygen is not supplied to the chamber from any side nozzles. The gases supplied to top nozzle 145 and top vent 146 may be kept separate prior to flowing the gases into chamber 113, or the gases may be mixed in top plenum 148 before they flow into chamber 113. Separate sources of the same gas may be used to supply various portions of the chamber.

A remote microwave-generated plasma cleaning system 150 is provided to periodically clean deposition residues from chamber components. The cleaning system includes a remote microwave generator 151 that creates a plasma from a cleaning gas source 134E (e.g., molecular fluorine, nitrogen trifluoride, other fluorocarbons or equivalents) in reactor cavity 153. The reactive species resulting from this plasma are conveyed to chamber 113 through cleaning gas feed port 154 via applicator tube 155. The materials used to contain the cleaning plasma (e.g., cavity 153 and applicator tube 155) must be resistant to attack by the plasma. The distance between reactor cavity 153 and feed port 154 should be kept as short as practical, since the concentration of desirable plasma species may decline with distance from reactor cavity 153. Generating the cleaning plasma in a remote cavity allows the use of an efficient microwave generator and does not subject chamber components to the temperature, radiation, or bombardment of the glow discharge that may be present in a plasma formed in situ. Consequently, relatively sensitive components, such as electrostatic chuck 120, do not need to be covered with a dummy wafer or otherwise protected, as may be required with an in situ plasma cleaning process. In FIG. 1, the plasma-cleaning system 150 is shown disposed above the chamber 113, although other positions may alternatively be used.

A baffle 161 may be provided proximate the top nozzle to direct flows of source gases supplied through the top nozzle into the chamber and to direct flows of remotely generated plasma. Source gases provided through top nozzle 145 are directed through a central passage 162 into the chamber, while remotely generated plasma species provided through the cleaning gas feed port 154 are directed to the sides of the chamber 113 by the baffle 161.

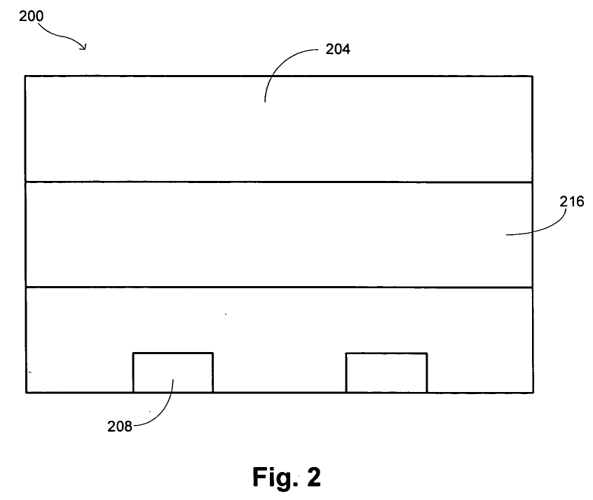

In embodiments of the invention, each of the coil assemblies comprises a magnetic-field concentrator, which may be formed of a magneto-dielectric material. FIG. 2 shows coil assembly 200, with the coil designated as element 208 and the magnetic-field concentrator designated as element 204. The assemblies are formed over a ceramic plate 216 that forms part of a frame for holding the coil 208. A more detailed description of an exemplary structure of a coil assembly in provided in commonly assigned U.S. Pat. No. 6,192,829, entitled “ANTENNA COIL ASSEMBLIES FOR SUBSTRATE PROCESSING CHAMBERS,” the entire disclosure of which is incorporated herein by reference.

The magneto-dielectric material that may be comprised by the additional magnetic-field concentrator may be formed from a magnetic powder composite. As used herein, reference to a “magneto-dielectric material” is intended to refer to a composition that comprises a ferromagnetic material and a dielectric material, with the dielectric material provided at greater than 2 wt. % of the material. With such relative compositions of the ferromagnetic and dielectric materials, the dielectric properties of the material dominate over the magnetic properties, although magnetic properties are still manifested. The material is thus capable of concentrating magnetic fields while at the same time suppressing the formation of eddy currents that lead to excess heat generation. In some instances, the dielectric material is provided at greater than 10 wt. % of the material. A suitable ferromagnetic material comprises iron and a suitable dielectric material comprises an epoxy resin. Magneto-dielectric materials may be formed into a solid mass from the magnetic-powder composite by a number of known techniques, including casting and centrifuging.

For purposes of illustration, the inventors have performed a number of experiments using a particular magneto-dielectric material, namely FERROTRON® 559, which is a commercially available material formed with pure iron powder uniformly dispersed in an insulating plastic binder. The material is known to have high-permeability low-hysteresis losses and temperature resistance at least up to 300° C. While this material is described in detail in discussing the experiments carried out by the inventors, other magneto-dielectric materials may alternatively be used and specific references to this material are not intended to be limiting. For example, other materials that meet the stated requirements for magneto-dielectric materials are available from other manufacturers such as Höganäs AB.

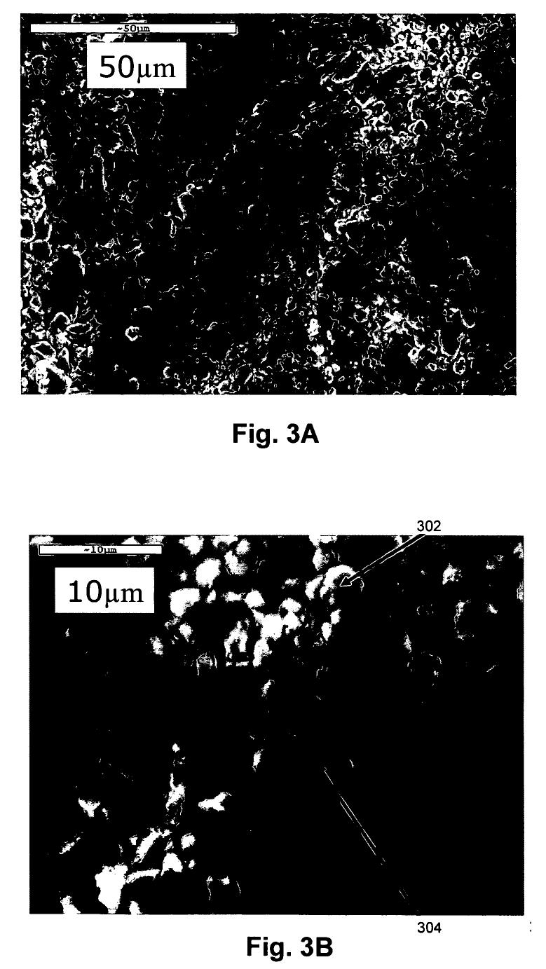

The physical structure of FERROTRON® 559 is evident from FIGS. 3A and 3B, which are micrographs taken of the material by the inventors at different scales. With the lower-magnification scale of FIG. 3A, it is evident that iron particles are relatively evenly distributed throughout the material, although there may be occasional large clusters, such as is visible in the lower left corner of the micrograph. At the high-magnification scale of FIG. 3B, it is easily seen that the structure of the material has individual soft iron particles 302 embedded into a thermoplastic binder. Energy-dispersive spectroscopy (“EDS”) measurements performed by the inventors confirm that FERROTRON® 559 comprises pure iron dispersed in an insulating plastic binder.

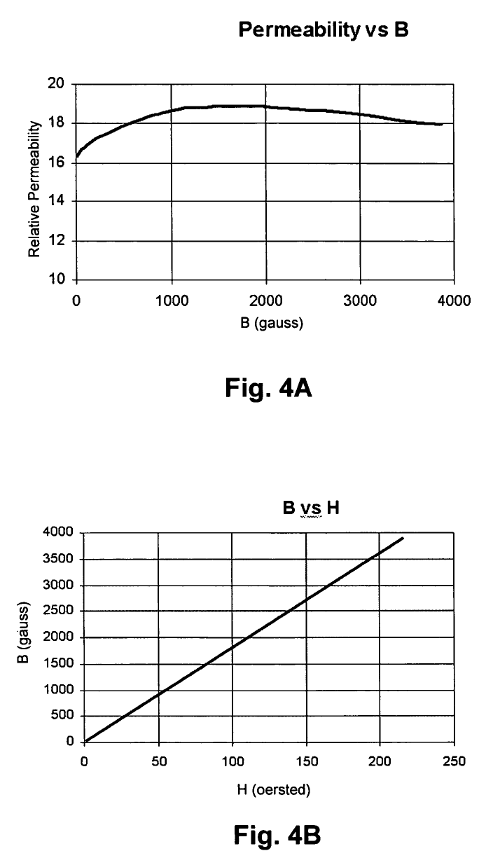

Measurements of the magnetic properties of the material are summarized graphically in FIGS. 4A and 4B. FIG. 4A plots the relative magnetic permeability of the material measured as a function of magnetic flux density B. The relative permeability shows little variation, increasing from its zero-flux value of about 16.5 by about 20% at a flux density of about 1500 gauss, and dropping off slowly at higher flux densities. The low-hysteretic-loss properties of the material are evident from FIG. 4B, which plots the magnetic flux density B as a function of magnetic field H over a range of about 0-250 oersted. The results show no discernible hysteresis. A summary of the reported materials properties for FERROTRON® 559 is set forth in Table I.

TABLE I
Materials Properties of Exemplary Magneto-Dielectric Material

| Property | Value |
|---|---|
| Specific Gravity | 5.8-5.9 g/cm³ |
| Thermal Conductivity | 4.6 W/mK |
| Coefficient of Thermal | 3.2 × 10⁻⁵ K⁻¹ |
| Expansion | |
| Hardness | Rockwell M70 |
| Saturation Flux Density Bₘ | 1.2 T |
| Electrical Resistivity | ˜1.0 × 10³ Ωcm |
| Residual Permittivity εᵣ | ˜20 |
| Relative Permeability μᵣ | 18 |
| Maximum Operating | ˜300° C. |
| Temperature | |
| Optimal Operating | ˜250° C. |
| Temperature | |
| Curie Temperature | >300° C. |
| Typical Frequency Range | 10-1000 kHz |

Certain of the properties identified in the table are within desired ranges, such as may characterize the desired qualitative features of the magneto-dielectric material as having relatively low electrical conductivity, relatively high magnetic conductivity, and relatively high thermal conductivity. For example, the thermal conductivity of the exemplary material has the characteristic of being greater than 2 W/mK and is within a range of 2-10 W/mK. Similarly, the electrical resistivity has the characteristic of being greater than 10³ Ω cm and being within the range of 10³-10⁸ Ω cm. Further, the magnetic properties have a residual permittivity εᵣ greater than 15 and within the range of 15-25 and a relative permeability μᵣ greater than 14 and within the range of 14-50.

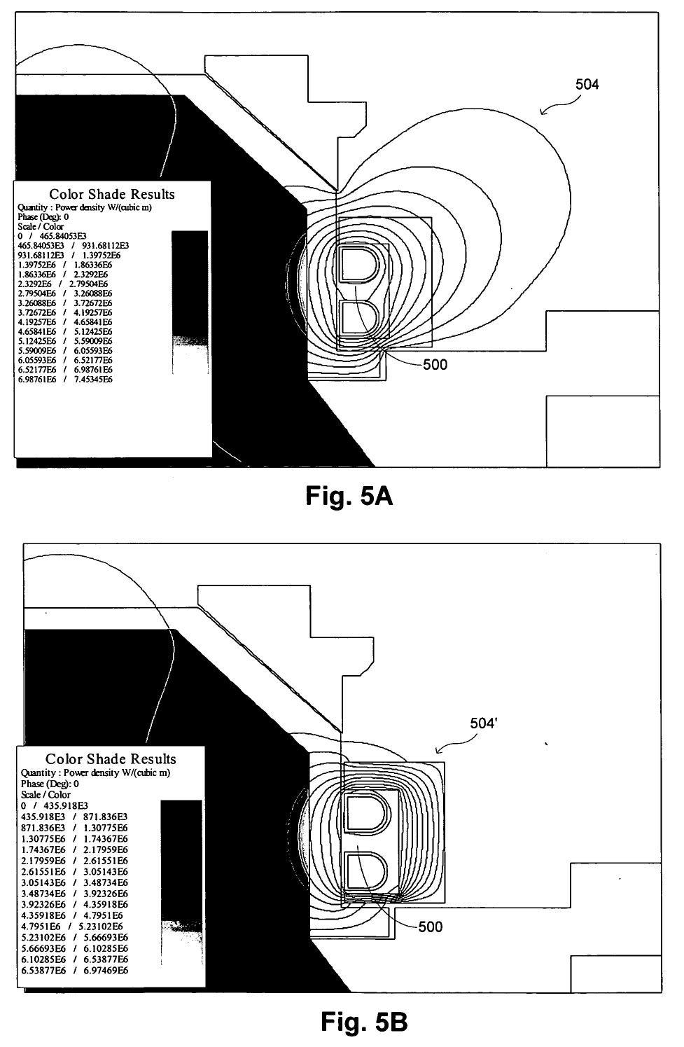

Preliminary to performing experimental measurements, the inventors also carried out simulations to forecast the anticipated effect of including magneto-dielectric material as part of the coil assemblies. The results of such simulations are provided in FIGS. 5A and 5B, which respectively show results without and with the magneto-dielectric material included. While the drawings additionally show shading that represents changes in the power density, attention is drawn more particularly to the field lines 504 and 504′ around the coil assembly 500. The results qualitatively show the objective of concentrating the field lines around the coil assembly. Quantitative analysis of the simulation results indicates that the ion density of the plasma may consequently be increased by at least 40% with a given power input as a consequence. At the same time, the thermal budget increase for the same power input shows no more than a 10% increase and losses to the concentrator are very small, being less than 1% and resulting from the formation of only small magnetic eddy currents. The simulation results also show that a relative permeability of about 14-18 is sufficiently high to achieve the desired results, with no noticeable difference in results being apparent with a further increase in the relative permeability to 50. The inductance of the coil, which has a bare inductance Z_{bare} of about 18 Ω is approximately doubled to about 34 Ω. For the same power induced in the plasma, there is a reduction in current by a factor of about 1.8-1.9.

To quantify the effect of the magnetic concentrator under operational conditions with a plasma formed within the chamber, measurements were taken of the voltage and current at the top and side coils for a number of different power configurations. The results of such measurements are summarized in Table II. In the table, results of measurements are provided for both the rms voltage Vᵣₘₛ and the rms current Iᵣₘₛ. The magnitude of the percentage change from baseline results measured without the presence of the concentrator to measurements with the concentrator are highlighted. Table II shows the results for a 4.5 kW power input to the coils for a plasma formed in a chamber having a pressure of 5.5 mtorr.

TABLE II
Source RF Voltage-Current Comparisons

| Vᵣₘₛ (V) | | | | | | Iᵣₘₛ (mA) | | | | | |
|---|---|---|---|---|---|---|---|---|---|---|---|
| Top Coil | | | Side Coil | | | Top Coil | | | Side Coil | | |
| No | | | No | | | No | | | No | | |
| Conc | Conc | % Chg. | Conc | Conc | % Chg. | Conc | Conc | % Chg. | Conc | Conc | % Chg. |
| 1000 | 867 | −13.3 | 844 | 825 | −2.3 | 49.7 | 25.6 | −48.5 | 75.9 | 49.5 | −34.8 |

The results summarized in Table II show that in addition to some voltage reduction at the coils that include the magneto-dielectric material, there is a current reduction of about 35-50% at those coils. Since the ohmic heating loss varies as I²R for a coil resistance R, the reduction in ohmic heating loss is significant, i.e. on the order of 60-75%. The results show generally that there is a greater reduction in both the voltage and current at the top coils than at the side coils. That the loss attributable to the magneto-dielectric concentrator is small has also been confirmed by temperature measurements of the concentrator during operation at 80° C., which is much less than the measured dome temperature of 170° C. and much less than the rated operating temperature of the material of 250° C.

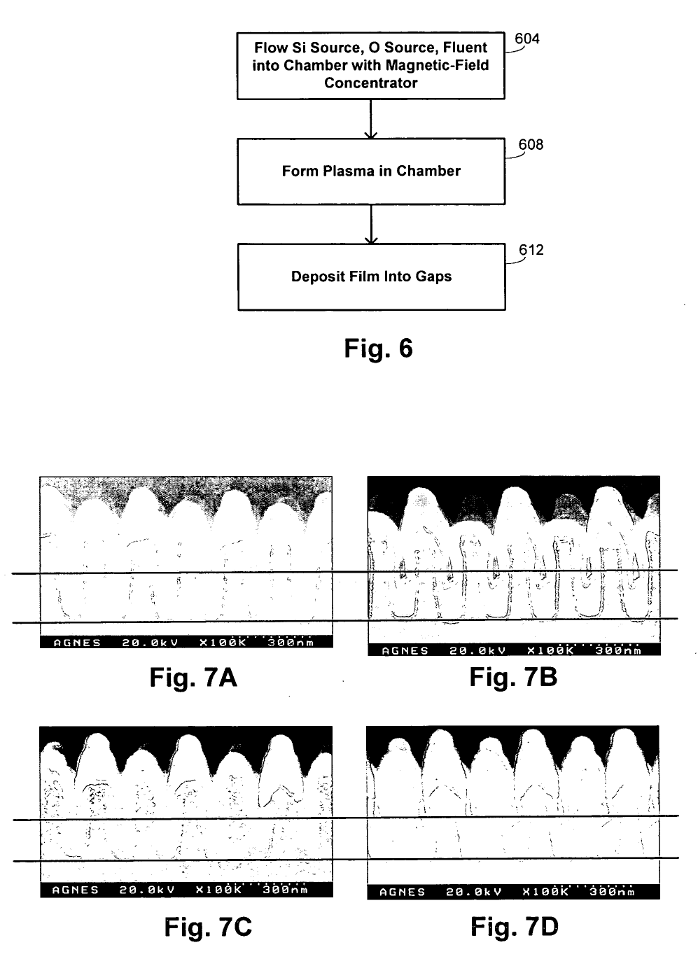

The substantial improvement in plasma characteristics that results from use of the magneto-dielectric material permits a reduction in bottom-up nonuniformity during gapfill processes. A general gapfill process that may be implemented with embodiments of the invention is shown with the flow diagram of FIG. 6. To deposit a SiO₂ film over a substrate that includes adjacent raised features defining gaps in structure, flows of a silicon source, an oxygen source, and a fluent gas are provided to a process chamber of an ICP system that includes the magnetic-field concentrator as part of the coil assemblies. At block 608, a plasma is formed inductively within the chamber with the gaseous flows so that the film is deposited over the substrate and within the gaps at block 612.

The effect of including the magneto-dielectric material has been evaluated experimentally by the inventors by using a Langmuir probe to compare ion saturation currents at the center and at the edge of a wafer for a specific power input. The results of such comparisons are summarized in Table III. Again, the table presents baseline values determined when the recipes were run without the presence of the magneto-dielectric material with values determined when run with the magneto-dielectric material. The percentage changes in ion-saturation current are highlighted for measurements performed both at the center of a wafer and at the edge of wafer.

TABLE III
Langmuir-Probe Comparison of Ion-Saturation Currents
Ion-Saturation Current (mA)

| | Center | | | Edge | | |
|---|---|---|---|---|---|---|
| RF Power | No Conc | Conc | % Chg | No Conc | Conc | % Chg |
| Top 4.5 kW | 550 | 745 | 35.5 | 422 | 557 | 32.0 |
| Side 4.5 kW | 370 | 488 | 21.1 | 321 | 383 | 19.3 |

The results of these measurements show a consistent increase in ion-saturation currents of more than 15% resulting from the use of magneto-dielectric material.

In addition to increasing the ion density in the plasma, the inclusion of magneto-dielectric material with the top and/or side coils may thus also be used to improve plasma uniformity by thereby increasing the side/top coupling efficiency. Advantageously, the consequent reduction in the range nonuniformity of the plasma ion density permits gapfill characteristics to be made more uniform at the center and edge of wafers. This is illustrated with the micrographs shown in FIGS. 7A-7D, which provide a comparison of gapfill effects without and with the magneto-dielectric concentrators at both the center and edge of wafers. FIGS. 7A and 7C (the left panels in the drawing) are micrographs taken of gapfill structures at the center of a wafer, while FIGS. 7B and 7D (the right panels) are micrographs taken of gapfill structures at the edge of the wafer. FIGS. 7A and 7B (the top panels) are micrographs taken for a gapfill process in a chamber that did not include the magneto-dielectric material, while FIGS. 7C and 7D (the bottom panels) are micrographs taken for a gapfill process in a chamber that did include the magneto-dielectric material. The nonuniformity has been quantized by tuning bottom-up values to be the same in the two instances, as denoted schematically over the micrographs with the horizontal lines in FIGS. 7A-7D. A summary of the measurements taken to perform such a calculation is provided in Tables IVA and IVB. These measurements were taken for a 200-mm-diameter wafer.

TABLE IVA
Comparison of Center and Edge Gapfill Without Magneto-Dielectric

| | Measurements (nm) | | | |
|---|---|---|---|---|
| | Bottom-up | | | Normalized |
| | Gapfill | Thickness | Si Depth | Bottom-up Gapfill |
| Center | 172 | 156 | 302 | 1.10 |
| Edge | 115 | 150 | 302 | 0.77 |

Center-to-edge Nonuniformity = 30%

TABLE IVB
Comparison of Center and Edge Gapfill With Magneto-Dielectric

| | Measurements (nm) | | | |
|---|---|---|---|---|
| | Bottom-up | | | Normalized |
| | Gapfill | Thickness | Si Depth | Bottom-up Gapfill |
| Center | 162 | 151 | 296 | 1.07 |
| Edge | 131 | 149 | 320 | 0.88 |

Center-to-edge Nonuniformity = 16%

As the results show, the center-edge-nonuniformity is decreased from about 30% to about 16% by including the magneto-dielectric material in the coil assemblies, an improvement of about 50% of the nonuniformity value.

The experimental results also confirm the simulation results of an increase in plasma ion density. Using a process that has only side power, the ion density was found to increase with the presence of the concentrator by 42% at a side power of 4.8 kW and by 61% at a side power of 2.4 kW. It is thus evident that embodiments of the invention permit a simultaneous increase in ion density with an improvement in uniformity across a wafer. Without being bound to any particular mechanism by which these results are achieved, the inventors note that the magneto-dielectric material is believed to act to shield aluminum-containing parts of the system from exposure to magnetic fields by concentrating the magnetic field in the region of the coils. The losses in the aluminum-containing parts drop by about 3.7 times, with the overall coupling efficiency improvement depending on losses to the aluminum-containing parts. For the same power transferred into the plasma, the voltage on the inductor is believed to be about the same with and without the magneto-dielectric concentrator. Consequently, the capacitive coupling is similar and ion bombardment and ion heating are similar, while the ion density is increased. The maximum magnetic flux density in the magneto-dielectric concentrator is about 200 gauss, which is significantly lower than the limit of magneto-dielectric materials so that magnetic loss is low.

Having fully described several embodiments of the present invention, many other equivalents or alternative embodiments of the present invention will be apparent to those skilled in the art. For example, while the invention has been described for a particular example of magneto-dielectric material, other magneto-dielectric materials may be used in alternative embodiments. The scope of the invention should, therefore, be determined not with reference to the above description, but instead should be determined with reference to the appended claims along with their full scope of equivalents.

What is claimed is:

1. A substrate processing system comprising:
a housing defining a process chamber;
a substrate holder disposed within the process chamber and configured to support a substrate during substrate processing;
a gas-delivery system configured to introduce a gas into the process chamber;
a pressure-control system for maintaining a selected pressure within the process chamber;
a high-density-plasma generating system operatively coupled with the process chamber, the high-density-plasma generating system including a coil for inductively coupling energy into a plasma formed within the process chamber and including magneto-dielectric material proximate the coil for concentrating a magnetic field generated by the coil; and
a controller for controlling the gas-delivery system, the pressure-control system, and the high-density-plasma generating system.

2. The substrate processing system recited in claim 1 wherein the magneto-dielectric material comprises a ferromagnetic material and a dielectric material, the dielectric material provided at greater than 2 wt. % of the magneto-dielectric material.

3. The substrate processing system recited in claim 2 wherein the ferromagnetic material comprises iron.

4. The substrate processing system recited in claim 2 wherein the dielectric material comprises an epoxy resin.

5. The substrate processing system recited in claim 1 wherein the magneto-dielectric material comprises a ferromagnetic material and a dielectric material, the dielectric material provided at greater than 10 wt. % of the magneto-dielectric material.

6. The substrate processing system recited in claim 1 wherein the magneto-dielectric material has a thermal conductivity greater than 2 W/mK.

7. The substrate processing system recited in claim 1 wherein the magneto-dielectric material has a thermal conductivity between 2 and 10 W/mK.

8. The substrate processing system recited in claim 1 wherein the magneto-dielectric material has an electrical resistivity greater than 10³ Ω cm.

9. The substrate processing system recited in claim 1 wherein the magneto-dielectric material has an electrical resistivity between 10³ and 10⁸ Ω cm.

10. The substrate processing system recited in claim 1 wherein the magneto-dielectric material has a residual permittivity greater than 15.

11. The substrate processing system recited in claim 1 wherein the magneto-dielectric material has a residual permittivity between 15 and 25.

12. The substrate processing system recited in claim 1 wherein the magneto-dielectric material has a relative permeability greater than 14.

13. The substrate processing system recited in claim 1 wherein the magneto-dielectric material has a relative permeability between 14 and 50.

14. A substrate processing system comprising:
a housing defining a process chamber;
a substrate holder disposed within the process chamber and configured to support a substrate during substrate processing;
a gas-delivery system configured to introduce a gas into the process chamber;
a pressure-control system for maintaining a selected pressure within the process chamber;
a high-density-plasma generating system operatively coupled with the process chamber, the high-density-plasma generating system including a coil for inductively coupling energy into the plasma and including a magneto-dielectric material for concentrating a magnetic field generated by the coil, wherein:
the magneto-dielectric material comprises a ferromagnetic material and a dielectric material, the dielectric material provided at greater than 2 wt. % of the magneto-dielectric material; and
the magneto-dielectric material has a thermal conductivity greater than 2 W/mK, an electrical resistivity greater than 10³ Ω cm, a residual permittivity greater than 15 and a relative permeability greater than 14; and
a controller for controlling the gas-delivery system, the pressure-control system, and the high-density-plasma generating system.

15. A method for depositing a film on a substrate disposed in a substrate processing chamber, the method comprising:
flowing a process gas into the substrate processing chamber;
inductively forming a plasma having an ion density greater than 10¹¹ ions/cm³ from the process gas with a coil;
concentrating a magnetic field generated by the coil with a magneto-dielectric material disposed proximate the coil; and
depositing the film over the substrate with the plasma in a process that has simultaneous deposition and sputtering components.

16. The method recited in claim 15 wherein:
the substrate has a trench formed between adjacent raised surfaces; and
depositing the film over the substrate with the plasma comprises depositing the film within the trench.

17. The method recited in claim 15 wherein the process gas comprises a silicon source, an oxygen source, and a fluent gas.

18. The method recited in claim 17 wherein the fluent gas comprises He.

19. The method recited in claim 17 wherein the fluent gas comprises H₂.

20. The method recited in claim 15 wherein the magneto-dielectric material comprises a ferromagnetic material and a dielectric material, the dielectric material provided at greater than 2 wt. % of the magneto-dielectric material.

21. The method recited in claim 20 wherein the ferromagnetic material comprises iron.

22. The method recited in claim 20 wherein the dielectric material comprises an epoxy resin.

23. The method recited in claim 15 wherein the magneto-dielectric material comprises a ferromagnetic material and a dielectric material, the dielectric material provided at greater than 10 wt. % of the magneto-dielectric material.

24. The method recited in claim 15 wherein the magneto-dielectric material has a thermal conductivity greater than 2 W/mK.

25. The method recited in claim 15 wherein the magneto-dielectric material has a thermal conductivity between 2 and 10 W/mK.

26. The method recited in claim 15 wherein the magneto-dielectric material has an electrical resistivity greater than 10³ Ω cm.

27. The method recited in claim 15 wherein the magneto-dielectric material has an electrical resistivity between 10³ and 10⁸ Ω cm.

28. The method recited in claim 15 wherein the magneto-dielectric material has a residual permittivity greater than 15.

29. The method recited in claim 15 wherein the magneto-dielectric material has a residual permittivity between 15 and 25.

30. The method recited in claim 15 wherein the magneto-dielectric material has a relative permeability greater than 14.

31. The method recited in claim 15 wherein the magneto-dielectric material has a relative permeability between 14 and 50.

32. A method of depositing a silica glass film on a substrate disposed in a substrate processing chamber, the substrate having a trench formed between adjacent raised surfaces, the method comprising:
flowing a process gas comprising a silicon source, an oxygen source, and a fluent gas into the substrate processing chamber;
inductively forming having an ion density greater than 10¹¹ ions/cm³ from the process gas with a coil;
concentrating a magnetic field generated by the coil with a magneto-dielectric material, wherein:
the magneto-dielectric material comprises a ferromagnetic material and a dielectric material, the dielectric material provided at greater than 2 wt. % of the magneto-dielectric material; and
the magneto-dielectric material has a thermal conductivity greater than 2 W/mK, an electrical resistivity greater than 10³ Ω cm, a residual permittivity greater than 15 and a relative permeability greater than 1; and
depositing the film over the substrate and within the trench in a process that has simultaneous deposition and sputtering components.

33. The method recited in claim 32 wherein the fluent gas comprises He.

34. The method recited in claim 32 wherein the fluent gas comprises H₂.
